(19) United States
(12) Patent Application Publication
(10) Pub. No.: US 2020/0381619 A1
(43) Pub. Date: Dec. 3, 2020

(54) SEMICONDUCTOR DEVICE

(71) Applicant: Samsung Electronics Co., Ltd., Suwon-si (KR)

(72) Inventors: Kyung Hwan LEE, Hwaseong-si (KR); Chang Seok KANG, Seongnam-si (KR); Yong Seok KIM, Suwon-si (KR); Kohji KANAMORI, Seoul (KR); Hui Jung KIM, Seongnam-si (KR); Jun Hee LIM, Seoul (KR)

(21) Appl. No.: 16/998,542

(22) Filed: Aug. 20, 2020

Related U.S. Application Data
(63) Continuation of application No. 16/172,830, filed on Oct. 28, 2018.

(30) Foreign Application Priority Data
Apr. 23, 2018 (KR) 10-2018-0046826

(51) Int. Cl. H01L 45/00; H01L 27/24; H01L 27/102

(52) U.S. Cl. CPC H01L 45/1206; H01L 45/144; G11C 11/39; H01L 45/06; H01L 27/1027; H01L 27/249

(57) ABSTRACT

A semiconductor device includes interlayer insulating layers and horizontal structures alternately and repeatedly disposed on a semiconductor substrate, separation structures extending in a direction perpendicular to an upper surface of the semiconductor substrate on the semiconductor substrate, to extend in a first horizontal direction parallel to the upper surface of the semiconductor substrate, and vertical structures disposed between the separation structures. Each of the horizontal structures includes a plurality of semiconductor regions, and the plurality of semiconductor regions of each of the plurality of semiconductor regions include a first semiconductor region and a second semiconductor region sequentially arranged in a direction away from a side surface of a corresponding one of the vertical structures and having different conductivity types.

### CROSS-REFERENCE TO RELATED APPLICATION(S)

This application is a Continuation of U.S. patent application Ser. No. 16/172,830, filed on Oct. 28, 2018, which claims priority under 35 U.S.C. § 119 to Korean Patent Application No. 10-2018-0046826 filed on Apr. 23, 2018 in the Korean Intellectual Property Office, the disclosure of each of which is incorporated herein by reference in its entirety.

### BACKGROUND

### 1. Field

The present inventive concept relates to a semiconductor device, and more particularly, to a semiconductor device including horizontal structures having a plurality of semiconductor regions of different conductivity types, and a method of forming the same.

### 2. Description of Related Art

In general, semiconductor devices such as DRAMs or PRAMs include two-dimensionally arranged data storage elements. Semiconductor devices including two-dimensionally arranged data storage elements may have limitations in improving the degree of integration.

### SUMMARY

An aspect of the present inventive concept is to provide a semiconductor device in which the degree of integration may be improved.

An aspect of the present inventive concept is to provide a method of forming a semiconductor device in which the degree of integration may be improved.

According to an aspect of the present inventive concept, a semiconductor device includes a vertical structure disposed on a semiconductor substrate and extending in a direction perpendicular to an upper surface of the semiconductor substrate, and a horizontal structure connected to a side surface of the vertical structure, and parallel to the upper surface of the semiconductor substrate. The horizontal structure includes a plurality of semiconductor regions sequentially arranged, in a direction away from the side surface of the vertical structure and parallel to the upper surface of the semiconductor substrate, and the plurality of semiconductor regions form at least one PN junction.

According to an aspect of the present inventive concept, a semiconductor device includes interlayer insulating layers and horizontal structures alternately and repeatedly stacked on a semiconductor substrate, and vertical structures disposed on a semiconductor substrate and extending in a direction perpendicular to an upper surface of the semiconductor substrate. Each of the horizontal structures includes a plurality of semiconductor regions and a first conductive pattern adjacent to the plurality of semiconductor regions, the plurality of semiconductor regions of each of the horizontal structures include a first semiconductor region and a second semiconductor region, sequentially arranged in a direction away from a side surface of a corresponding one of the vertical structures and having different conductivity types, and each first conductive pattern is spaced apart from a corresponding one of the vertical structures.

According to an aspect of the present inventive concept, a semiconductor device includes interlayer insulating layers and horizontal structures alternately and repeatedly disposed on a semiconductor substrate, separation structures disposed between the horizontal structures, extending in a direction perpendicular to an upper surface of the semiconductor substrate on the semiconductor substrate, and extending in a first horizontal direction parallel to the upper surface of the semiconductor substrate, and vertical structures disposed between the separation structures. Each of the horizontal structures includes a plurality of semiconductor regions, and the plurality of semiconductor regions of each of the plurality of semiconductor regions include a first semiconductor region and a second semiconductor region sequentially arranged in a direction away from a side surface of a corresponding one of the vertical structures and having different conductivity types.

According to an aspect of the present inventive concept, a method of forming a semiconductor device includes forming interlayer insulating layers and sacrificial layers alternately and repeatedly stacked on a semiconductor substrate, forming vertical patterns penetrating through the interlayer insulating layers and the sacrificial layers, each of the vertical patterns including a semiconductor layer, forming trenches exposing the sacrificial layers while penetrating through the interlayer insulating layers and the sacrificial layers, the vertical patterns being located between the trenches, forming empty spaces by removing the sacrificial layers exposed, to expose semiconductor layers of the vertical patterns, forming a plurality of semiconductor regions in the empty spaces, the plurality of semiconductor regions being formed of a semiconductor material epitaxially grown from the semiconductor layers exposed, and forming separation structures filling the trenches.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1A is a perspective view schematically illustrating an example of a semiconductor device according to an example embodiment of the present inventive concept;

FIG. 1B is a partial perspective view illustrating a portion of FIG. 1A according to example embodiments;

FIG. 2 is a perspective view schematically illustrating a modified example of a semiconductor device according to an example embodiment of the present inventive concept;

FIG. 3 is a perspective view schematically illustrating a modified example of a semiconductor device according to an example embodiment of the present inventive concept;

FIG. 4A is a perspective view schematically illustrating a modified example of a semiconductor device according to an example embodiment of the present inventive concept;

FIG. 4B is a partial perspective view illustrating a portion of FIG. 4A;

FIG. 5 is a partial perspective view schematically illustrating a modified example of the semiconductor device according to an example embodiment of the present inventive concept;

FIG. 6 is a perspective view schematically illustrating a modified example of the semiconductor device according to an example embodiment of the present inventive concept;

FIG. 7A is a perspective view schematically illustrating a modified example of a semiconductor device according to an example embodiment of the present inventive concept;

FIG. 7B is a partial perspective view illustrating a portion of FIG. 7A according to example embodiments;

FIG. 8 is a partial perspective view schematically illustrating a modified example of the semiconductor device according to an example embodiment of the present inventive concept;

FIG. 9 is a perspective view schematically illustrating a modified example of the semiconductor device according to an example embodiment of the present inventive concept;

FIGS. 10 to 12 and FIGS. 14 to 18 are perspective views schematically illustrating an example of a method of forming a semiconductor device according to an example embodiment of the present inventive concept; and

FIG. 13 is a perspective view schematically illustrating a modified example of the method of forming a semiconductor device according to an example embodiment of the present inventive concept.

### DETAILED DESCRIPTION

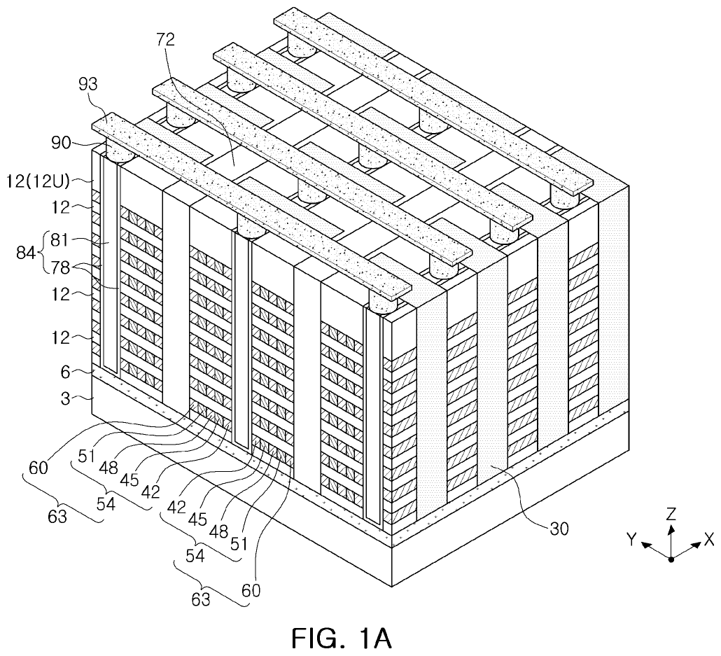

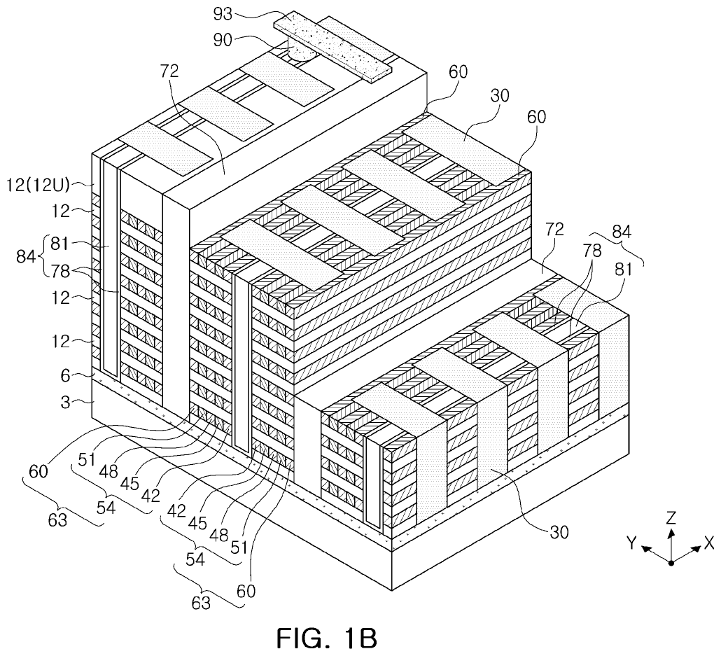

First, an example of a semiconductor device according to an example embodiment of the present inventive concept will be described with reference to FIGS. 1A and 1B. FIG. 1A is a schematic perspective view illustrating an example of a semiconductor device according to an example embodiment, and FIG. 1B is a partial perspective view of a portion of FIG. 1A according to example embodiments.

Referring to FIGS. 1A and 1B, horizontal structures 63 may be disposed on a semiconductor substrate 3. The horizontal structures 63 may be stacked while being spaced apart from each other in a vertical direction Z perpendicular to an upper surface of the semiconductor substrate 3. Each of the horizontal structures 63 may be parallel to the semiconductor substrate 3.

Interlayer insulating layers 12 may be disposed on the semiconductor substrate 3. The interlayer insulating layers 12 may be stacked while being spaced apart from each other in the vertical direction Z.

In one example, the horizontal structures 63 may be interposed between the interlayer insulating layers 12. For example, the interlayer insulating layers 12 and the horizontal structures 63 may be alternately and repeatedly stacked on the semiconductor substrate 3, and an uppermost layer of a stacked structure including the interlayer insulating layers 12 and the horizontal structures 63 may be an uppermost interlayer insulating layer 12U.

Vertical structures 84 extending in the vertical direction Z and penetrating through the horizontal structures 63 may be disposed on the semiconductor substrate 3. The vertical structures 84 may penetrate through the horizontal structures 63 and the interlayer insulating layers 12.

A lower insulating layer 6 may be disposed on the semiconductor substrate 3. The lower insulating layer 6 may be disposed to be lower than a position of the stacked structure including the interlayer insulating layers 12 and the horizontal structures 63. For example, the interlayer insulating layers 12 and the horizontal structures 63 may be disposed on the lower insulating layer 6. The lower insulating layer 6 may be disposed between the vertical structures 84 and the semiconductor substrate 3 to separate the vertical structures 84 from the semiconductor substrate 3. Thus, the vertical structures 84 may be spaced apart from the semiconductor substrate 3.

In an example embodiment, the lower insulating layer 6 may be referred to as an etch stop layer.

The lower insulating layer 6 may be formed of a material different from that of the interlayer insulating layers 12. For example, the interlayer insulating layers 12 may be formed of silicon oxide, and the lower insulating layer 6 may be formed of a material including a high dielectric such as aluminum oxide, aluminum nitride, or the like, but an example embodiment thereof is not limited thereto. The lower insulating layer 6 may be formed of various insulating materials.

Separation structures 72 may be disposed on the semiconductor substrate 3. The separation structures 72 may be in contact with the lower insulating layer 6. The separation structures 72 may be formed of an insulating material, for example silicon oxide. The separation structures 72 may be spaced apart from the semiconductor substrate 3.

The interlayer insulating layers 12 and the horizontal structures 63 may be disposed between the separation structures 72. The separation structures 72 may extend in the vertical direction Z on the semiconductor substrate 3, and may be disposed in such a manner that they penetrate through the interlayer insulating layers 12 and the horizontal structures 63.

The separation structures 72 may respectively have a linear shape extending in a first horizontal direction X. In this case, the first horizontal direction X may be parallel or horizontal to the semiconductor substrate 3.

Partition walls 30 passing through the horizontal structures 63 may be disposed between the separation structures 72. The partition walls 30 may be spaced apart from the separation structures 72. The partition walls 30 may penetrate through the horizontal structures 63 and the interlayer insulating layers 12. The partition walls 30 may be formed of an insulating material such as silicon oxide or the like.

Between any pair of separation structures 72 adjacent to each other, the partition walls 30 may be sequentially arranged in the first horizontal direction X and may be spaced apart from each other. The partition walls 30 may have a shape elongated in a second horizontal direction Y, for example, may have a bar shape. The second horizontal direction Y may be perpendicular to the first horizontal direction X, and may be parallel or horizontal to the semiconductor substrate 3.

The vertical structures 84 may be disposed between the partition walls 30, and may be spaced apart from each other by the partition walls 30. For example, each of the vertical structures 84 may be disposed between a pair of adjacent partition walls 30.

In an example, the vertical structures 84 may be in contact with the partition walls 30.

Each of the vertical structures 84 may include an external pattern 78 and an internal pattern 81. In each of the vertical structures 84, the internal pattern 81 may be pillar-shaped, and the external pattern 78 may be formed to cover both sides of the internal pattern 81 and a bottom surface of the internal pattern 81. In each of the vertical structures 84, the external pattern 78 may cover sides of the internal pattern 81 not in contact with the partition walls 30. In each of the vertical structures 84, the external pattern 78 may be interposed between the internal pattern 81 and the horizontal structure 63. The internal pattern 81 may be formed of a material having higher electrical conductivity than that of the external pattern 78.

In an example, the external pattern 78 may be formed of polysilicon, and the internal pattern 81 may be formed of a metal nitride such as TiN or the like, and/or a metal such as tungsten (W).

In another example, the external pattern 78 may be formed of mono-crystalline silicon. The mono-crystalline silicon may be formed from a polysilicon material by an annealing (e.g., laser annealing) or a metal induced lateral crystallization (MILC). In this case, the process of the annealing or the MILC may be performed before forming the internal pattern 81. In some examples, a semiconductor material other than silicon may be used for the external pattern 78 (whether in a mono-crystalline or polycrystalline form)

In another example, the external pattern 78 may be formed of a metal-silicide such as TiSi or the like, and the internal pattern 81 may be formed of a metal nitride such as TiN or the like and/or a metal such as W or the like.

In another example, the external pattern 78 may be formed of a metal nitride such as TiN or the like, and the internal pattern 81 may be formed of a metal such as W or the like.

In example embodiments, each of the vertical structures 84 may be formed of a single material layer. For example, each of the vertical structures 84 may be formed of a doped silicon material (e.g., a doped polysilicon material or a doped polysilicon-germanium material).

The horizontal structures 63 may have a form separated into two by the vertical structures 84 and the partition walls 30, between any pair of adjacent separation structures 72. For example, between a pair of adjacent separation structures 72, the vertical structures 84 and the partition walls 30 may pass through the horizontal structures 63 to allow the horizontal structures 63 to be spaced apart from each other in a second horizontal direction Y.

The horizontal structures 63 may include a plurality of semiconductor regions 54 and first conductive patterns 60. The first conductive patterns 60 may be interposed between the plurality of semiconductor regions 54 and the separation structures 72, and may be interposed between the partition walls 30 and the separation structures 72.

Second conductive patterns 93 may be disposed on the vertical structures 84. Contact plugs 90 may be disposed between the vertical structures 84 and the second conductive patterns 93. Thus, the vertical structures 84 may be electrically connected to the second conductive patterns 93 through the contact plugs 90.

For convenience of description, a single horizontal structure 63, among the horizontal structures 63, through which the vertical structures 84 and the partition walls 30 penetrate and are spaced apart from each other, between a pair of adjacent separation structures 72, will be described below. In addition, among the vertical structures 84, a single vertical structure 84 contacting the single horizontal structure 63 will be described below.

The horizontal structure 63 may include the plurality of semiconductor regions 54 and the first conductive pattern 60. The plurality of semiconductor regions 54 may be disposed between the first conductive pattern 60 and the vertical structure 84.

The plurality of semiconductor regions 54 may include semiconductor regions sequentially arranged in a direction away from a side surface of the vertical structure 84 and parallel to an upper surface of the semiconductor substrate 3. For example, the plurality of semiconductor regions 54 may include a first semiconductor region 42 and a second semiconductor region 45 that are sequentially arranged in a direction away from the side surface of the vertical structure 84 and parallel to the upper surface of the semiconductor substrate 3. The first and second semiconductor regions 42 and 45 may form a PN junction.

The plurality of semiconductor regions 54 may further include a third semiconductor region 48 and a fourth semiconductor region 51. The first semiconductor region 42, the second semiconductor region 45, the third semiconductor region 48 and the fourth semiconductor region 51 may be disposed to be sequentially arranged in a direction away from the side surface of the vertical structure 84 and parallel to the upper surface of the semiconductor substrate 3.

The plurality of semiconductor regions 54 may include an epitaxial semiconductor material epitaxially grown from a polysilicon material or a polysilicon-germanium material. For example, the first to fourth semiconductor regions 42, 45, 48 and 51 may be formed of an epitaxial semiconductor material. For example, the first semiconductor region 42 adjacent to the vertical structure 84, from among the plurality of semiconductor regions 54, may be formed of an epitaxial semiconductor material epitaxially grown from a polysilicon material or a polysilicon-germanium material.

The first and third semiconductor regions 42 and 48 may have a first conductivity type, and the second and fourth semiconductor regions 45 and 51 may have a second conductivity type different from the first conductivity type. Either of the first and second conductivity types may be a P-type, and the other may be an N-type. For example, the first and third semiconductor regions 42 and 48 may have a P-type conductivity, and the second and fourth semiconductor regions 45 and 51 may have an N-type conductivity.

The first to fourth semiconductor regions 42, 45, 48 and 51 of the plurality of semiconductor regions 54 may constitute a PNPN thyristor memory cell.

The semiconductor device may include a memory cell array having a plurality of memory cells. The memory cell array may be provided, for example, as a three-dimensional memory array structure. The three-dimensional memory array may have memory cells arrayed in the vertical direction and horizontal direction, and include a plurality of memory cells in which at least one memory cell is located over another memory cell (e.g., include vertical stacks of a plurality of memory cells). In example embodiments, the memory cell array may include the interlayer insulating layers 12 and the horizontal structures 63 stacked with each other and the vertical structures 84. For example, at least one memory cell may include the first to fourth semiconductor regions 42, 45, 48 and 51 of the plurality of semiconductor regions 54 constituting a PNPN thyristor memory cell.

The plurality of memory cells of the memory cell array may be coupled to a plurality of word lines and a plurality of bit lines. As an example, the first conductive patterns 60 may form the bit lines and the vertical structures 84 may form the word lines. As another example, the first conductive patterns 60 may form the word lines and the vertical structures 84 may form the bit lines.

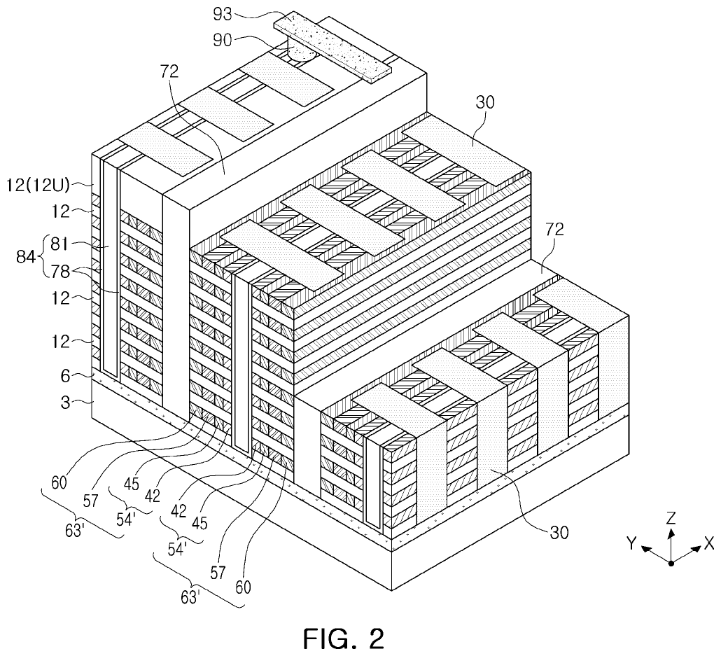

As described above, the semiconductor device according to an example embodiment, including the first to fourth semiconductor regions 42, 45, 48 and 51 constituting the PNPN thyristor memory cell, may be a thyristor memory device, but an example embodiment thereof is not limited thereto. For example, the semiconductor device according to an example embodiment may be modified into a memory device including a resistance variable element. As described above, a modified example of the semiconductor device according to an example embodiment, which may be a memory device including a resistance variable element, will be described with reference to FIG. 2.

FIG. 2 is a partial perspective view that may correspond to FIG. 1B, illustrating a modified example of the semiconductor device according to an example embodiment.

In a modified example, referring to FIG. 2, the horizontal structure 63 (see FIGS. 1A and 1B) including the first conductive pattern 60 and the plurality of semiconductor regions 54 constituting a thyristor, described above with reference to FIGS. 1A and 1B, may be replaced by a horizontal structure 63′ including a first conductive pattern 60, a data storage element 57, and a plurality of semiconductor regions 54′ that may constitute a PN diode. The first conductive pattern 60 of the horizontal structure 63′ may be substantially the same as the first conductive pattern 60 (see FIGS. 1A and 1B) described above with reference to FIGS. 1A and 1B.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the horizontal structure 63′, the plurality of semiconductor regions 54′ that may constitute a PN diode may include a first semiconductor region 42 and a second semiconductor region 45, the same as those described above with reference to FIGS. 1A and 1B. Thus, the first semiconductor region 42 and the second semiconductor region 45 may be disposed to be sequentially arranged in a direction away from a side of a vertical structure 84, similarly to the description above with reference to FIGS. 1A and 1B, and may form a PN conjunction. The data storage element 57 may be disposed between the first conductive pattern 60 and the plurality of semiconductor regions 54′. The data storage element 57 may be a resistance variable element of which a resistance value may change according to a current or a voltage. For example, the data storage element 57 may be an element to store information in a resistive random access memory (ReRAM) device or may be an element to store information in a phase-change random access memory (PRAM) device. For example, the data storage element 57 may include a transition metal oxide (TMO) layer, a phase change material layer, a solid electrolyte layer, or a polymer layer. For example, the data storage element 57 may include a TiO layer, a TaO layer, an NiO layer, a ZrO layer, or a HfO layer. The data storage element 57 may have relatively high resistivity or relatively low resistivity in response to an applied electrical signal. For example, when the data storage element 57 includes a transition metal oxide (TMO) layer such as a TiO film, a TaO film, a NiO film, a ZrO film, or a HfO film, the data storage element 57 may exhibit relatively high resistivity in a reset state. When a write current flows in the data storage element 57, a path through which a current may flow may be generated in the data storage element 57, thereby exhibiting relatively low resistivity. Alternatively, the data storage element 57 may include a phase change memory material capable of changing a phase from an amorphous phase having a high specific resistance to a crystalline phase having a low specific resistance, or from a crystalline phase to an amorphous phase, depending on temperature and time based on heating by an applied current. The phase change memory material may be a chalcogenide material including germanium (Ge), stibium (Sb), and/or tellurium (Te), or may be a material including at least one of Te or selenium (Se) and at least one of Ge, Sb, bismuth (Bi), plumbum (Pb), stannum (Sn), arsenic (As), sulfur (S), silicon (Si), phosphorus (P), oxygen (O), nitrogen (N) or indium (In). The phase change memory material may be formed of a material having a superlattice structure that may be formed by repetitive stack of GsTe-SbTe, an In—Sb—Te (IST) material or a Bi—Sb—Te (BST) material.

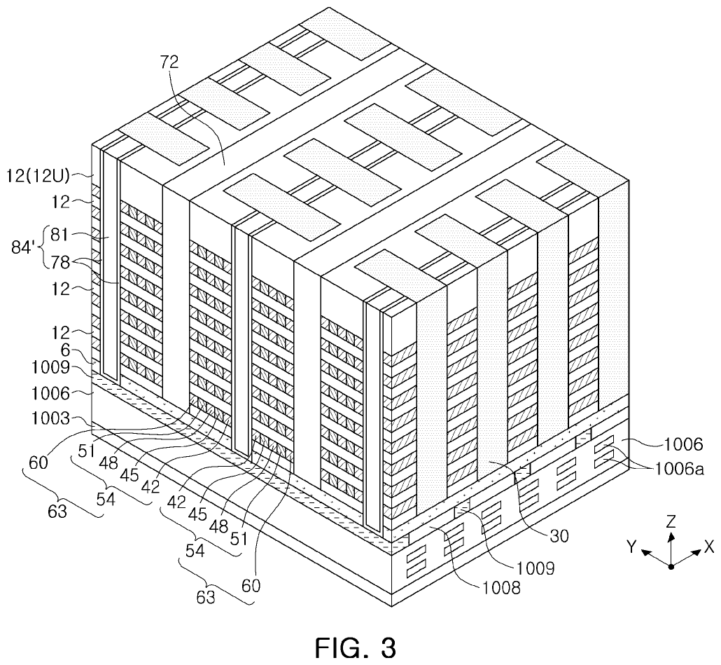

Referring again to FIGS. 1A and 1B, the second conductive patterns 93 described above may be disposed above the vertical structures 84, but an example embodiment thereof is not limited thereto. For example, the second conductive patterns 93 may be modified to be disposed below the vertical structures 84, which will be described with reference to FIG. 3 as an example.

FIG. 3 is a schematic perspective view illustrating a modified example of the semiconductor device according to an example embodiment.

Referring to FIG. 3, a lower structure 1006 may be disposed on a semiconductor substrate 1003 below the memory cell array (e.g., the interlayer insulating layers 12 and the horizontal structures 63′ stacked with each other and the vertical structures 84). Second conductive patterns 1009 may be disposed on the lower structure 1006. In this case, an additional insulating layer may be disposed between the conductive patterns 1009 and the lower structure 1006. Gap fill insulating layers 1008 may be disposed between the second conductive patterns 1009. In some examples, the lower structure 1006 may be disposed above the memory cell array (e.g., the interlayer insulating layers 12 and the horizontal structures 63′ stacked with each other and the vertical structures 84).

In an illustrative example, the lower structure 1006 may be a structure in which a peripheral circuit 1006a of a memory device may be located. The peripheral circuit 1006a may control an operation of the memory cells for the semiconductor device. For example, the peripheral circuit 1006a may include one or more of an address buffer, a command decoder, a row decoder, a column decoder, a control circuit, a voltage generator, etc. For example, the peripheral circuit 1006a may read data from the memory cell and write data to the memory cell.

The lower insulating layer 6, the same as that described above with reference to FIGS. 1A and 1B, may be disposed on the second conductive patterns 1009 and the gap fill insulating layers 1008. The horizontal structures 63, the interlayer insulating layers 12, the separation structures 72 and the partition walls 30, the same as those described above with reference to FIGS. 1A and 1B, may be disposed on the lower insulating layer 6.

Vertical structures 84′ may be disposed to penetrate through the horizontal structures 63 and the interlayer insulating layers 12, while extending downwardly, to penetrate through the lower insulating layer 6 to be electrically connected to the second conductive patterns 1009. Each of the vertical structures 84′ may include an internal pattern 81 and an external pattern 78, the same as those described above with reference to FIGS. 1A and 1B.

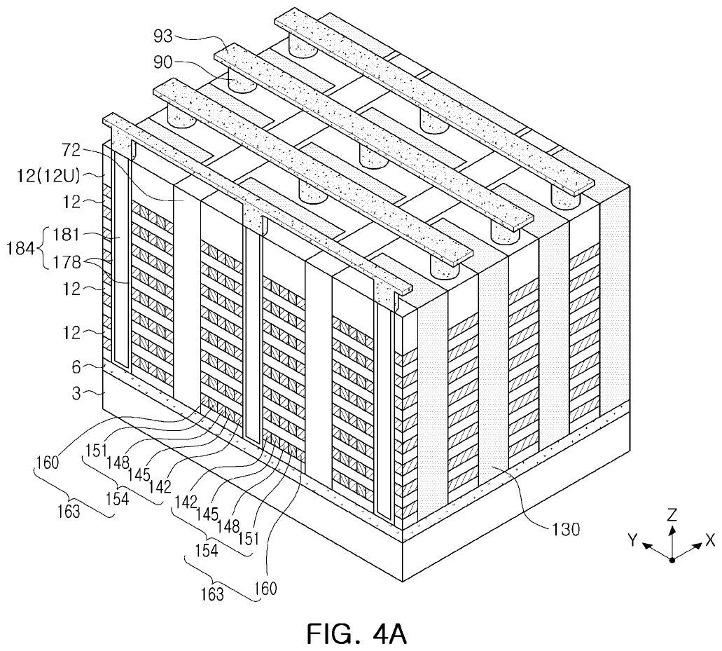

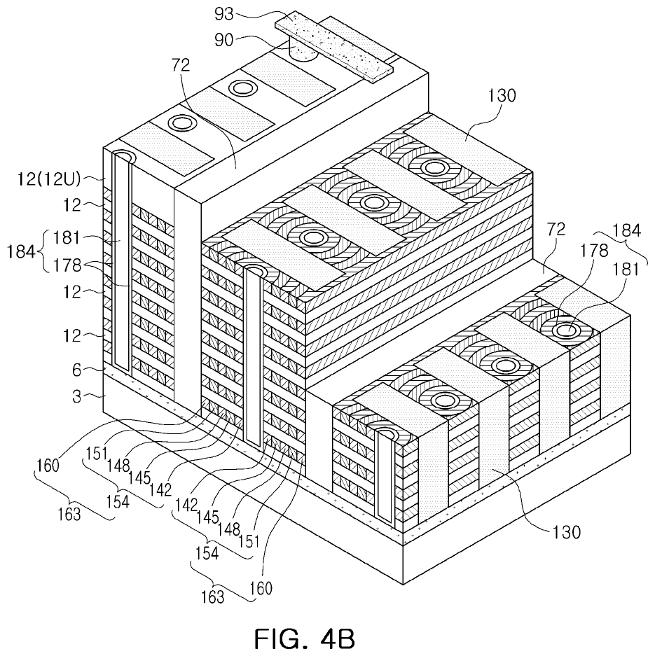

Referring again to FIGS. 1A and 1B, the vertical structures 84 may be in contact with the partition walls 30, but an example embodiment thereof is not limited thereto. For example, the vertical structures 84 and the partition walls 30 may be modified to be spaced apart from each other. An example of such a modification will be described with reference to FIGS. 4A and 4B.

FIG. 4A is a schematic perspective view illustrating a modified example of the semiconductor device according to an example embodiment, and FIG. 4B is a partial perspective view illustrating a portion of FIG. 4A.

Referring to FIGS. 4A and 4B, the semiconductor substrate 3, the lower insulating layer 6, the interlayer insulating layers 12 and the separation structures 72, the same as those described above with reference to FIGS. 1A and 1B, may be disposed. Horizontal structures 163 may be disposed on the lower insulating layer 6, to be stacked while being spaced apart from each other in a Z direction perpendicular to an upper surface of the semiconductor substrate 3. The interlayer insulating layers 12 and the horizontal structures 163 may be alternately and repeatedly stacked.

The partition walls 130 may be disposed between the separation structures 72, to pass through the horizontal structures 163 and the interlayer insulating layers 12. The partition walls 130 may be formed of an insulating material such as silicon oxide or the like. The partition walls 130 may be spaced apart from the separation structures 72.

Between the separation structures 72, vertical structures 184 may be disposed to pass through the horizontal structures 163 and the interlayer insulating layers 12. Each of the vertical structures 184 may include an internal pattern 181 and an external pattern 178 covering a bottom surface of the internal pattern 181 while surrounding a side surface of the internal pattern 181. The internal pattern 181 may be formed of the same material as that of the internal pattern 81 described above with reference to FIGS. 1A and 1B. The external pattern 178 may be formed of the same material as that of the external pattern 78 described above with reference to FIGS. 1A and 1B.

The vertical structures 184 may respectively be disposed between adjacent partition walls 130. In an example, the vertical structures 184 may be spaced apart from the partition walls 130.

Each of the horizontal structures 163 may include a plurality of semiconductor regions 154 and first conductive patterns 160, between a pair of separation structures 72 adjacent to each other. For example, in the horizontal structures 163, the plurality of semiconductor regions 154 may be disposed between the first conductive patterns 160.

Between a pair of separation structures 72 adjacent to each other, the partition walls 130, the plurality of semiconductor regions 154 and the vertical structures 184 may be disposed between the first conductive patterns 160.

The plurality of semiconductor regions 154 may include a first semiconductor region 142, a second semiconductor region 145, a third semiconductor region 148, and a fourth semiconductor region 151. The first semiconductor regions 142 may be respectively disposed to surround the respective vertical structures 184.

Between a pair of separation structures 72 adjacent to each other, the second semiconductor region 145, the third semiconductor region 148 and the fourth semiconductor region 151 may be disposed to be sequentially arranged in a direction away from the first semiconductor region 142.

One first semiconductor region 142 may be disposed to surround a side surface of the external pattern 178 of one of the vertical structures 184. Thus, between one pair of adjacent partition walls 130, one of the vertical structures 184, and the plurality of semiconductor regions 154 including one of the first semiconductor regions 142 surrounding a side surface of the vertical structure 184, may be disposed.

The first and third semiconductor regions 142 and 148 may have a first conductivity type, and the second and fourth semiconductor regions 145 and 151 may have a second conductivity type different from the first conductivity type. Either of the first and second conductivity types may be a P-type, and the other may be an N-type. For example, the first and third semiconductor regions 142 and 148 may have a P-type conductivity, and the second and fourth semiconductor regions 145 and 151 may have an N-type conductivity. Thus, the first to fourth semiconductor regions 142, 145, 148 and 151 of the plurality of semiconductor regions 154 may constitute a PNPN thyristor memory cell, the same as that described above with respect to FIGS. 1A and 1B.

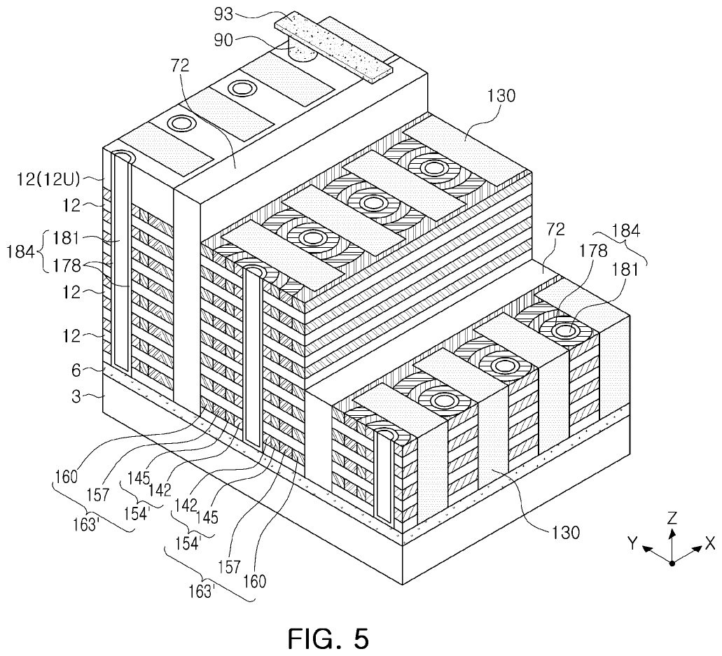

The horizontal structures 163 described above may include the first to fourth semiconductor regions 142, 145, 148 and 151 constituting a PNPN thyristor memory cell, but an example embodiment thereof is not limited thereto. A modified example of the horizontal structures 163 will be described with reference to FIG. 5.

FIG. 5 is a partial perspective view schematically illustrating a modified example of the semiconductor device according to an example embodiment.

In a modified example, referring to FIG. 5, the horizontal structure 163 (see FIGS. 4A and 4B) including the first conductive pattern 160 and the plurality of semiconductor regions 154 constituting a thyristor, described above with reference to FIGS. 4A and 4B, may be replaced by a horizontal structure 163′ including a first conductive pattern 160, a data storage element 157, and a plurality of semiconductor regions 154′ that may constitute a PN diode. The first conductive pattern 160 of the horizontal structure 163′ may be substantially the same as the first conductive pattern 160 (see FIGS. 4A and 4B) described above with reference to FIGS. 4A and 4B.

In the horizontal structure 163′, the plurality of semiconductor regions 154′ that may constitute a PN diode, may include the first semiconductor region 142 and the second semiconductor region 145, the same as those described above with reference to FIGS. 4A and 4B. Thus, the first semiconductor region 142 may be disposed to surround a side surface of the vertical structure 184 similarly to the example embodiment described above with reference to FIGS. 4A and 4B, and may constitute a PN diode together with the second semiconductor region 145.

The data storage element 157 may be disposed between the first conductive pattern 160 and the plurality of semiconductor regions 154′. The data storage element 157 may be a resistance variable element. For example, the data storage element 157 may be an element to store information in a resistive RAM (ReRAM) device or an element to store information in a phase change RAM (PRAM) device.

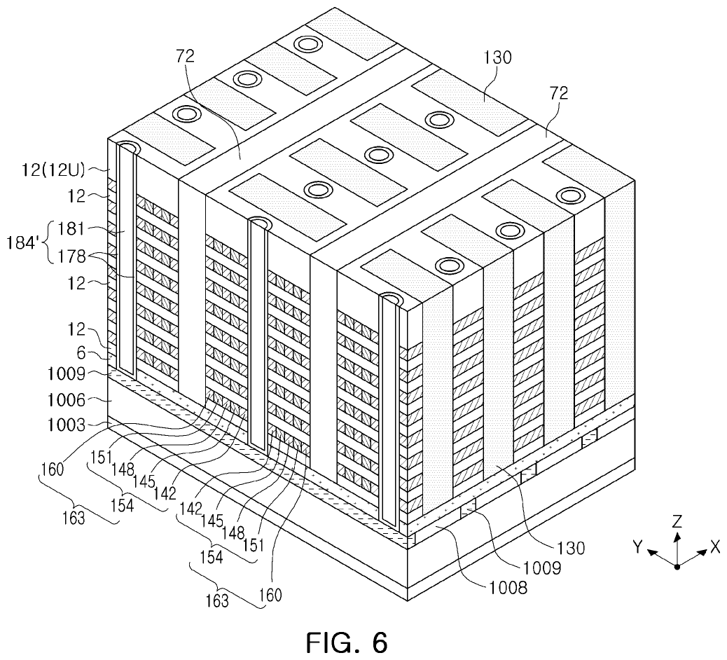

Referring again to FIGS. 4A and 4B, the contact plugs 90 and the second conductive patterns 93, the same as those described above with reference to FIGS. 1A and 1B, may be disposed on the vertical structures 184, but an example embodiment thereof is not limited thereto and may be modified. Such a modified example will be described with reference to FIG. 6.

FIG. 6 is a perspective view schematically illustrating a modified example of the semiconductor device according to an example embodiment.

In a modified example, referring to FIG. 6, the semiconductor substrate 1003, the lower structure 1006, the second conductive patterns 1009 and the gap fill insulating layers 1008, the same as those described above with reference to FIG. 3, may be disposed.

The lower insulating layer 6, the same as that described above with reference to FIGS. 1A and 1B, may be disposed on the second conductive patterns 1009 and the gap fill insulating layers 1008. The horizontal structures 163 and the partition walls 130, the same as those described above with reference to FIGS. 4A and 4B, may be disposed on the lower insulating layer 6. In addition, the interlayer insulating layers 12 and the separation structures 72, the same as those described above with reference to FIGS. 1A and 1B, may be disposed on the lower insulating layer 6.

Vertical structures 184′ may be disposed to penetrate through the horizontal structures 163 and the interlayer insulating layers 12 and may extend downwardly thereof to penetrate through the lower insulating layer 6 to be electrically connected to the second conductive patterns 1009. Each of the vertical structures 184′ may include the internal pattern 181 and the external pattern 178, identical to those described above with reference to FIGS. 4A and 4B.

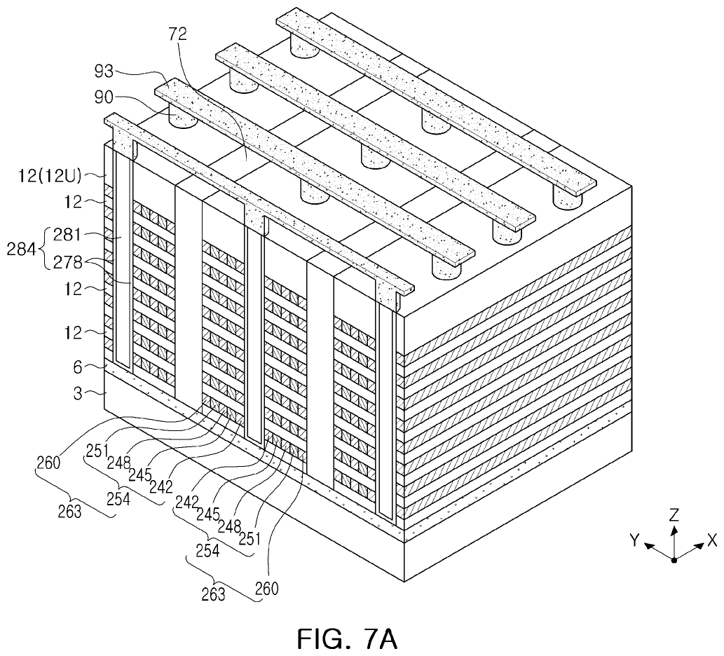

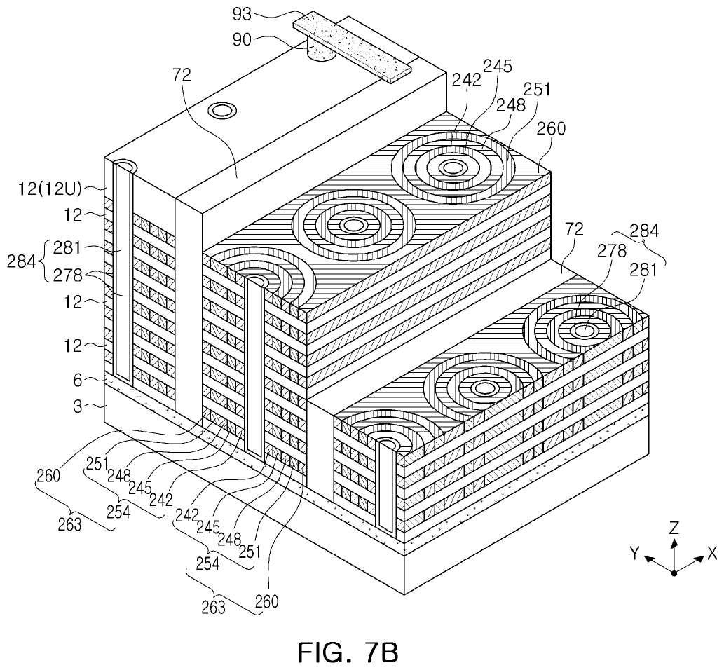

Next, a modified example of the semiconductor device according to an example embodiment will be described with reference to FIGS. 7A and 7B.

FIG. 7A is a perspective view schematically illustrating a modified example of the semiconductor device according to an example embodiment, and FIG. 7B is a partial perspective view illustrating a portion of FIG. 7A according to example embodiments.

Referring to FIGS. 7A and 7B, the semiconductor substrate 3, the lower insulating layer 6, the interlayer insulating layers 12 and the separation structures 72, the same as those described above with reference to FIGS. 1A and 1B, may be provided. For example, in FIGS. 7A and 7B, the partition walls 30 of FIGS. 1A and 1B or the partition walls 130 of FIGS. 4A and 4B are not formed. Horizontal structures 263, which may be alternately stacked with the interlayer insulating layers 12, may be disposed on the lower insulating layer 6.

Vertical structures 284 may be disposed to penetrate through the horizontal structures 284 and the interlayer insulating layers 12. Each of the vertical structures 284 may include an internal pattern 281 and an external pattern 278 covering a bottom surface of the internal pattern 281 while surrounding a side surface of the internal pattern 281. The internal pattern 281 may be formed of the same material as that of the internal pattern 81 described above with reference to FIGS. 1A and 1B, and the external pattern 278 may be formed of the same material as that of the external pattern 78 described above with reference to FIGS. 1A and 1B.

Each of the horizontal structures 263 may include a plurality of semiconductor regions 254 and a first conductive pattern 260, between a pair of separation structures 72 adjacent to each other.

The plurality of semiconductor regions 254 may be disposed to surround sides of the respective vertical structures 284. For example, in a single vertical structure 284, the plurality of semiconductor regions 254 may include a first semiconductor region 242 surrounding a side of the vertical structure 284, a second semiconductor region 245 surrounding the first semiconductor region 242, a third semiconductor region 248 surrounding the second semiconductor region 245, and a fourth semiconductor region 251 surrounding the third semiconductor region 248. The first conductive pattern 260 may be disposed between the plurality of semiconductor regions 254 to surround the plurality of semiconductor regions 254, between one pair of separation structures 72 adjacent to each other.

The first and third semiconductor regions 242 and 248 may have a first conductivity type, and the second and fourth semiconductor regions 245 and 251 may have a second conductivity type different from the first conductivity type. Either of the first and second conductivity types may be a P-type, and the other may be an N-type. For example, the first and third semiconductor regions 242 and 248 may have a P-type conductivity, and the second and fourth semiconductor regions 245 and 251 may have an N-type conductivity. Thus, the first to fourth semiconductor regions 242, 245, 248 and 251 of the plurality of semiconductor regions 254 may constitute a PNPN thyristor memory cell as illustrated above with reference to FIGS. 1A and 1B.

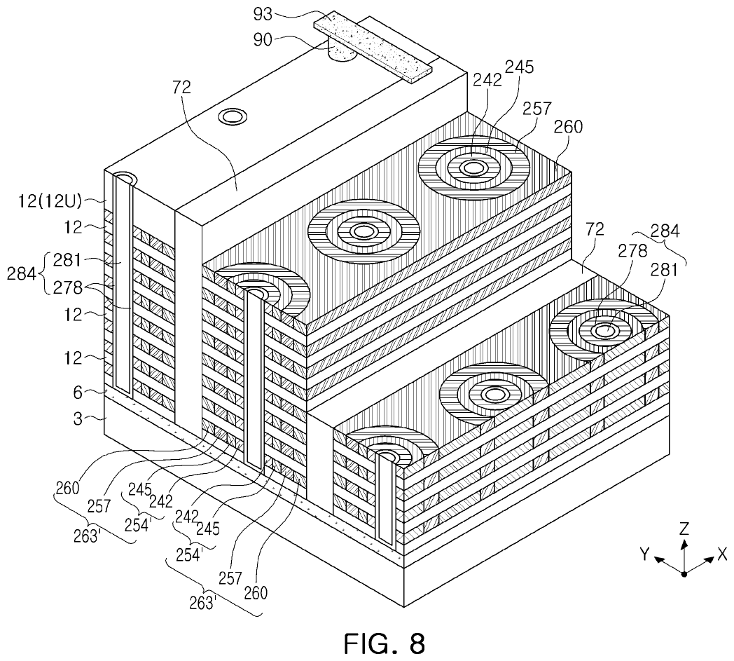

Each of the horizontal structures 263 may include the first to fourth semiconductor regions 242, 245, 248 and 251 that may constitute a PNPN thyristor memory cell, but an example embodiment thereof is not limited thereto. A modified example of the above-described horizontal structures 263 will be described with reference to FIG. 8.

FIG. 8 is a partial perspective view schematically illustrating a modified example of the semiconductor device according to an example embodiment.

In a modified example, referring to FIG. 8, the horizontal structure 263 (see FIG. 7A and FIG. 7B) including the first conductive pattern 260 and the plurality of semiconductor regions 254 constituting a thyristor, described above with reference to FIGS. 7A and 7B, may be replaced by a horizontal structure 263′ including a first conductive pattern 260, a data storage element 257, and a plurality of semiconductor regions 254′ that may constitute a PN diode. The first conductive pattern 260 of the horizontal structure 263′ may be substantially the same as the first conductive pattern 260 (see FIGS. 7A and 7B) described above with reference to FIGS. 7A and 7B.

In the horizontal structure 263′, the plurality of semiconductor regions 254′ that may constitute a PN diode, may include the first semiconductor region 242 and the second semiconductor region 245, the same as those described above with reference to FIGS. 7A and 7B. Thus, the first semiconductor region 242 may be disposed to surround a side surface of the vertical structure 284 similarly to the example embodiment described above with reference to FIGS. 7A and 7B, and may form a PN diode together with the second semiconductor region 245.

The data storage element 257 may be disposed between the first conductive pattern 260 and the plurality of semiconductor regions 254′. The data storage element 257 may surround the plurality of semiconductor regions 254′. The data storage element 257 may be a resistance variable element. For example, the data storage element 257 may be an element to store information in a resistive RAM (ReRAM) device or a phase change RAM (PRAM) device.

In example embodiments, adjacent pair of data storage elements 257 in the first horizontal direction X may be coupled to each other when a distance of adjacent pair of vertical structures 284 in the first horizontal direction X is reduced. In this case, the first conductive pattern 260 may be separated with respect to vertical structures 284 disposed in the first horizontal direction X, thus a density of memory cells of the semiconductor device may be increased.

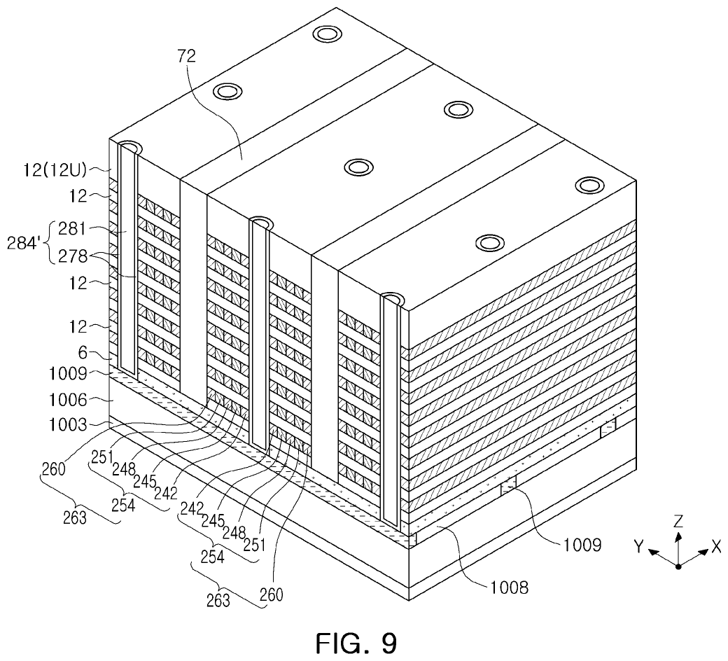

Referring again to FIGS. 7A and 7B, the contact plugs 90 and the second conductive patterns 93, the same as those described above with reference to FIGS. 1A and 1B, may be disposed on the vertical structures 284, but an example embodiment thereof is not limited thereto and may be modified. Such a modified example will be described with reference to FIG. 9.

FIG. 9 is a perspective view schematically illustrating a modified example of the semiconductor device according to an example embodiment.

In a modified example, referring to FIG. 9, the semiconductor substrate 1003, the lower structure 1006, the second conductive patterns 1009, and the gap fill insulating layers 1008, the same as those described above with reference to FIG. 3, may be provided.

The lower insulating layer 6, the same as that described above with reference to FIGS. 1A and 1B, may be disposed on the second conductive patterns 1009 and the gap fill insulating layers 1008. The horizontal structures 263, the same as those described above with reference to FIGS. 7A and 7B, may be disposed on the lower insulating layer 6. Further, the interlayer insulating layers 12 and the separation structures 72, the same as those described above with reference to FIGS. 1A and 1B, may be disposed on the lower insulating layer 6.

Vertical structures 284′ may be disposed to penetrate through the horizontal structures 263 and the interlayer insulating layers 12, while extending downwardly thereof, to penetrate through the lower insulating layer 6 to be electrically connected to the second conductive patterns 1009. Each of the vertical structures 284′ may include the internal pattern 281 and the external pattern 278, the same as those described above with reference to FIGS. 7A and 7B.

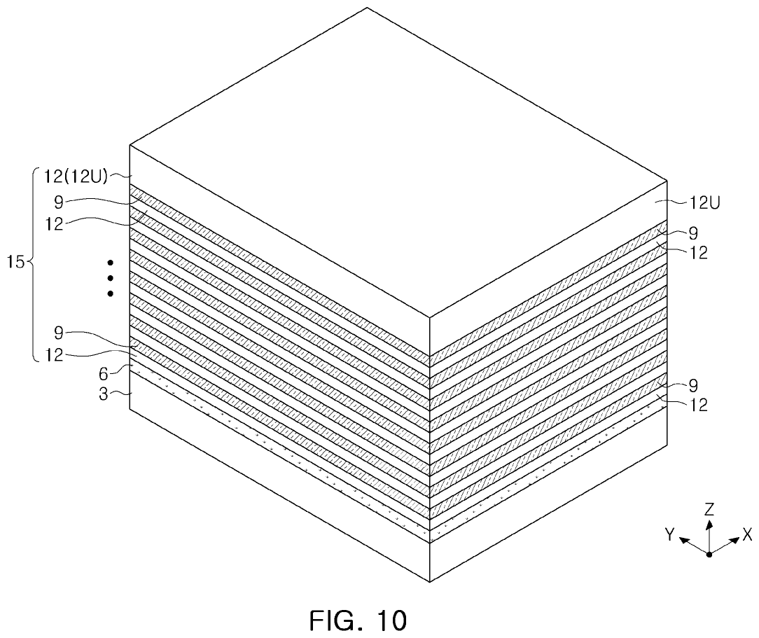

Next, examples of a method of forming a semiconductor device according to an example embodiment will be described with reference to referring to FIGS. 10 to 18.

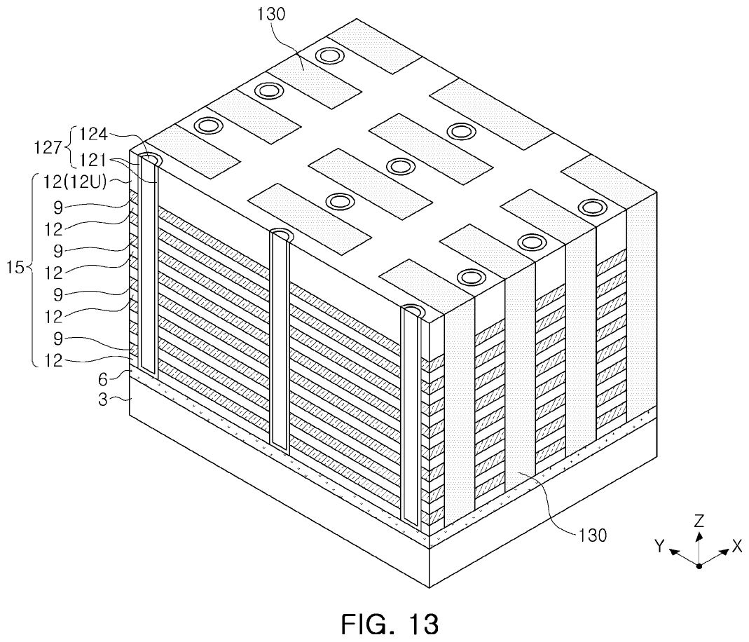

FIGS. 10 to 12 and FIGS. 14 to 18 are perspective views illustrating an example of a method of forming a semiconductor device according to an example embodiment, and FIG. 13 is a perspective view of a modified example of the method of forming a semiconductor device according to an example embodiment.

Referring to FIG. 10, a lower insulating layer 6 may be formed on a semiconductor substrate 3. A mold structure 15 may be formed on the lower insulating layer 6. The mold structure 15 may include interlayer insulating layers 12 and sacrificial layers 9 alternately and repeatedly stacked. Among the interlayer insulating layers 12 and the sacrificial layers 9, an uppermost interlayer insulating layer 12U may be an interlayer insulating layer 12. The interlayer insulating layers 12 may be formed of silicon oxide, and the sacrificial layers 9 may be formed of silicon nitride. The lower insulating layer 6 may be formed of an insulating material having an etch selectivity different from that of the mold structure 15, for example, an aluminum oxide and/or an aluminum nitride, or the like.

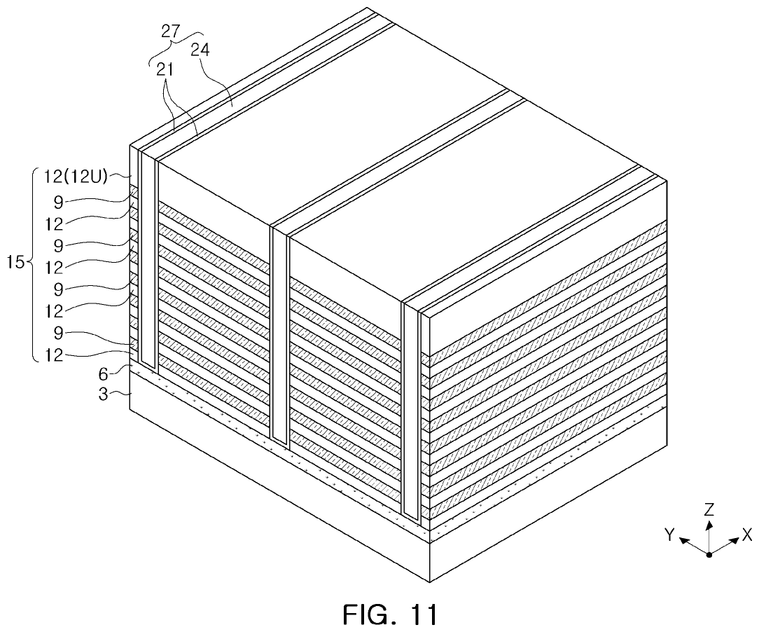

Referring to FIG. 11, vertical patterns 27 may be formed to extend in a vertical direction Z perpendicular to an upper surface of the semiconductor substrate 3, and may pass through the mold structure 15 to be parallel to each other, on the lower insulating layer 6. The vertical patterns 27 may have a linear form respectively extending in a first horizontal direction X. The first horizontal direction X may be a direction parallel to or horizontal to the semiconductor substrate 3.

Forming the vertical patterns 27 may include forming vertical structure trenches to penetrate through the mold structure 15 and expose the lower insulating layer 6 by etching the mold structure 15, forming a first layer 21 conformally covering side walls and bottom surfaces of the vertical structure trenches, and forming a second layer 24 filling the vertical structure trenches on the first layer 21.

The first layer 21 may be formed as a semiconductor layer, and the second layer 24 may be formed of a material different from that of the mold structure 15, such as an amorphous carbon material or the like. The first layer 21 may be formed of a polysilicon material layer or a polysilicon-germanium material layer. The second layer 24 may be a sacrificial layer or a sacrificial gap fill layer.

In another example, the vertical patterns 27 may be formed of a single material layer. For example, the vertical patterns 27 may be formed of a doped polysilicon material or a doped polysilicon-germanium material. In this case, the doped polysilicon material or the doped polysilicon-germanium material may be deposited to fill the vertical structure trenches.

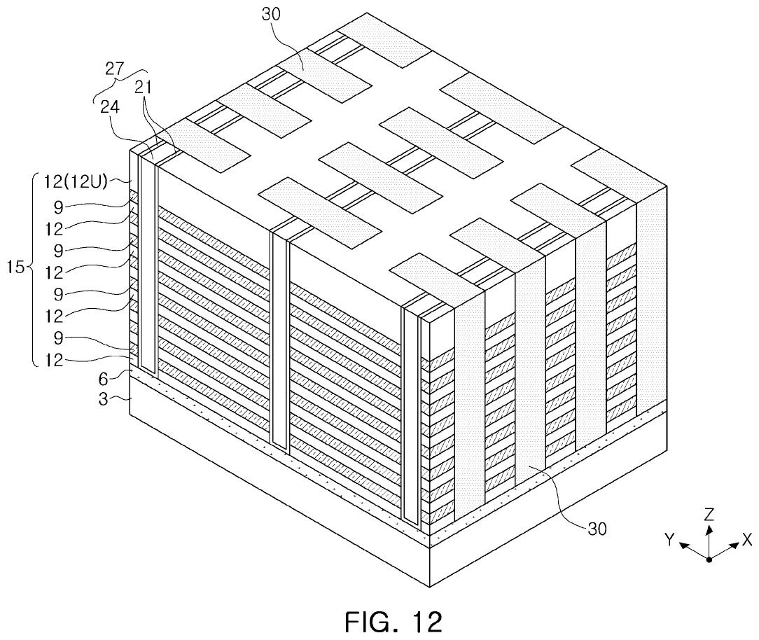

Referring to FIG. 12, partition walls 30 may be formed to penetrate through the mold structure 15 and the vertical patterns 27. In the first horizontal direction X, the vertical patterns 27 may be divided by the partition walls 30. Thus, the vertical patterns 27 may be formed between the partition walls 30. The partition walls 30 may be formed of silicon oxide.

The vertical patterns 27 and the partition walls 30, which may be formed by the method described above with reference to FIGS. 10 to 12, may be used in forming the vertical structures 84 and the partition walls 30 described above with reference to FIGS. 1A and 1B.

Next, a method of forming vertical patterns and partition walls, which may be used to form the vertical structures 184 and the partition walls 130 described above with reference to FIGS. 4A and 4B, will be described below.

Referring to FIGS. 10 and 13, vertical patterns 127 and partition walls 130 may be formed to pass through the mold structure 15 described above with reference to FIG. 10.

In an example, forming the vertical patterns 127 may include forming holes penetrating through the mold structure 15, forming a first layer 121 conformally covering sidewalls and bottom surfaces of the holes, and forming a second layer 124 filling the holes on the first layer 121. The first layer 121 may be formed of the same material as that of the first layer 21 (see FIG. 11) described above with reference to FIG. 11, and the second layer 124 may be formed of the same material as that of the second layer 24 (see FIG. 11) described above with reference to FIG. 11.

In an example, forming the partition walls 130 may include forming openings penetrating through the mold structure 15, and filling the openings with an insulating material, such as silicon oxide.

In an example, the vertical patterns 127 may be formed between the partition walls 130.

In an example, after the vertical patterns 127 are formed, the partition walls 130 may be formed.

In another example, the partition walls 130 may be formed before the vertical patterns 127 are formed.

Thus, a semiconductor substrate including the vertical patterns 27 and the partition walls 30 that may be formed by the method described above with reference to FIGS. 10 to 12, and a semiconductor substrate including the vertical patterns 127 and the partition walls 130 that may be formed by the method described above with reference to FIGS. 10 and 13, may be formed. A method to be described below may be identically applied to the semiconductor substrate including the vertical patterns 27 and the partition walls 30 that may be formed by the method described with reference to FIGS. 10 to 12, and the semiconductor substrate including the vertical patterns 127 and the partition walls 130 that may be formed by the method described with reference to FIGS. 10 and 13. Thus, mainly the semiconductor substrate including the vertical patterns 27 and the partition walls 30, which may be formed by the method described with reference to FIGS. 10 to 12, will be described below.

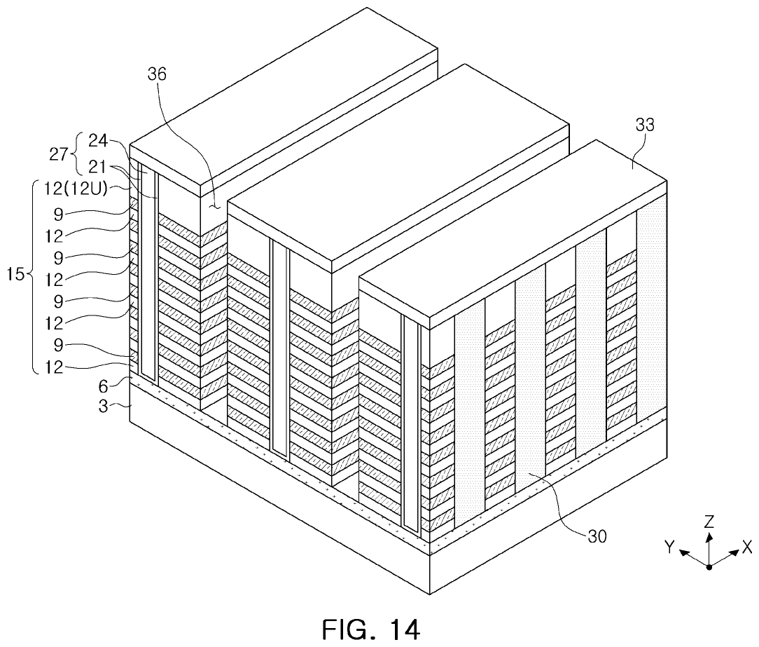

Referring to FIG. 14, a capping layer 33 may be formed on the mold structure 15.

The capping layer 33 may cover the vertical patterns 27 and the partition walls 30. The capping layer 33 may be formed of silicon oxide. Trenches 36 may be formed to penetrate through the capping layer 33 and the mold structure 15 to expose the lower insulating layer 6. The sacrificial layers 9 of the mold structure 15 may be exposed by the trenches 36.

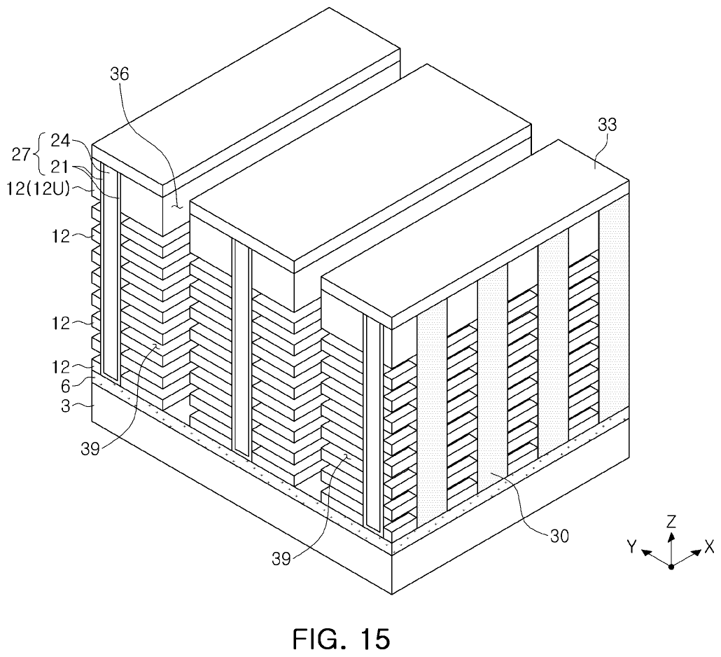

Referring to FIG. 15, the sacrificial layers 9 (see FIG. 14) may be selectively removed to form empty spaces 39 exposing side surfaces of the vertical patterns 27. Thus, the first layers 21 of the vertical patterns 27 may be exposed by the empty spaces 39.

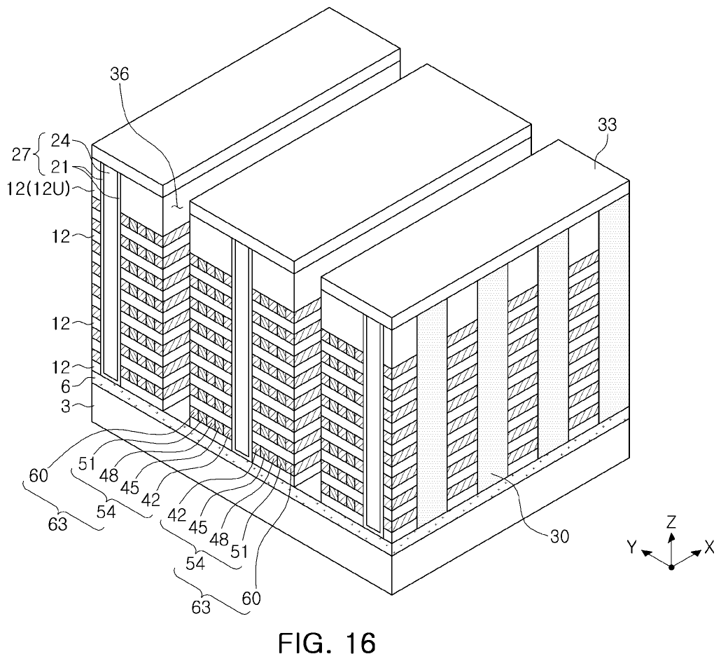

Referring to FIG. 16, horizontal structures 63 may be formed to fill the empty spaces 39 (see FIG. 15). The horizontal structures 63 may respectively be formed of a plurality of semiconductor regions 54 and a first conductive pattern 60.

The plurality of semiconductor regions 54 may be formed of an epitaxial semiconductor material epitaxially grown from the first layers 21 by performing an epitaxial growth process. For example, in a single horizontal structure 63, the plurality of semiconductor regions 54 may include a first semiconductor region 42 epitaxially grown from the first layer 21 of one of the vertical patterns 27 and in-situ doped with a P-type, a second semiconductor region 45 epitaxially grown from the first semiconductor region 42 and in-situ doped with an N-type, a third semiconductor region 48 epitaxially grown from the second semiconductor region 45 and in-situ doped with a P-type, and a fourth semiconductor region 51 epitaxially grown from the third semiconductor region 48 and in-situ doped with an N-type. Thus, the first to fourth semiconductor regions 42, 45, 48 and 51 may form a PNPN thyristor.

Forming the first conductive patterns 60 may include, after the formation of the plurality of semiconductor regions 54, filling the remainder of the empty spaces 39 (see FIG. 15) with a conductive material.

In an example, forming the first conductive patterns 60 may be performed by an epitaxial growth process after the plurality of semiconductor regions 54 are formed. In this case, the first conductive patterns 60 may be formed of polysilicon having an impurity concentration higher than that of the fourth semiconductor region 51, while having the same conductivity type as that of the fourth semiconductor region 51, for example, an N-type conductivity.

In another example, forming the first conductive patterns 60 may be performed by a deposition process and an impurity implantation process after the plurality of semiconductor regions 54 are formed. In this case, the first conductive patterns 60 may be formed of polysilicon having an impurity concentration higher than that of the fourth semiconductor region 51, while having the same conductivity type as that of the fourth semiconductor region 51, for example, an N-type conductivity. In this case, the impurity implantation process may be a plasma doping process in which impurities are implanted into side walls of the trenches 36.

In another example, forming the first conductive patterns 60 may include filling the remainder of the empty spaces 39 (see FIG. 15) with a semiconductor material after forming the plurality of semiconductor regions 54, and then, performing a silicide process in which the semiconductor material is formed as metal-silicide.

In another example, forming the first conductive patterns 60 may include filling the remainder of the empty spaces 39 (see FIG. 15) with a metal nitride such as TiN or the like and/or a metal such as tungsten (W) or the like, after forming the plurality of semiconductor regions 54.

In some examples, forming the first conductive patterns 60 may include etching material of the first conductive patterns 60 disposed in a bottom of the trenches 36.

The horizontal structures 63 may respectively be formed of the plurality of semiconductor regions 54 and the first conductive pattern 60 as described above with reference to FIGS. 1A and 1B, but an example embodiment thereof is not limited thereto. For example, the horizontal structures 63 described above may be formed as horizontal structures 63′ as described above with reference to FIG. 2. For example, after forming the empty spaces (39 in FIG. 15), an epitaxial growth process may be performed to form a plurality of semiconductor regions 54′ including the first and second semiconductor regions 42 and 45 by performing an epitaxial growth process, data storage elements 57 may be formed to be in contact with the plurality of semiconductor regions 54′ in the empty spaces 39 (see FIG. 15), and the first conductive patterns 60 may be formed in the empty spaces 39 (see FIG. 15). The first and second semiconductor regions 42 and 45 of the plurality of semiconductor regions 54′ may be PN diodes, and the data storage elements 57 may be resistance variable elements.

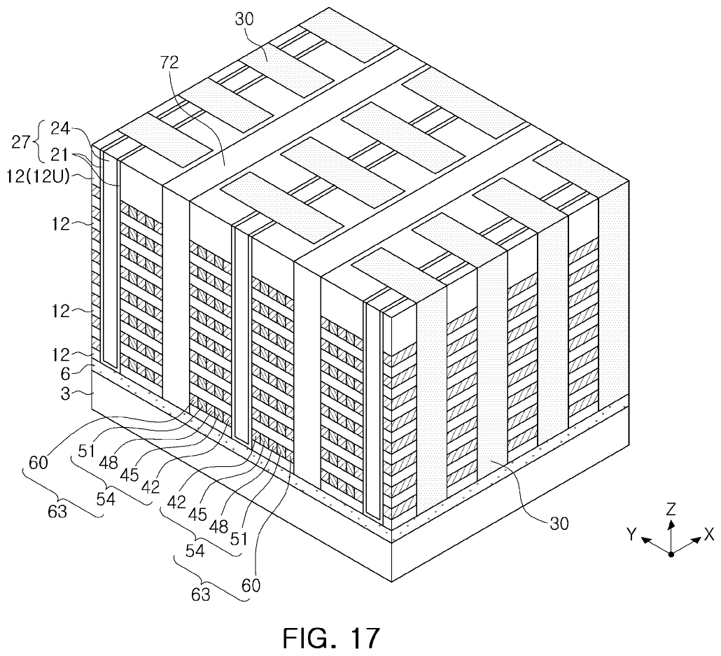

Referring to FIG. 17, after the horizontal structures 63 are formed, separation structures 72 may be formed to fill the trenches 36 (see FIG. 16).

The formation of the separation structures 72 may include forming an insulating material layer, for example, a silicon oxide layer, which fills the trenches 36 (see FIG. 16) while covering the capping layer 33 (see FIG. 16), and performing a planarization process until the partition walls 30 and the vertical patterns 27 are exposed. Thus, the separation structures 72 may be formed to remain in the trenches 36 (see FIG. 16). In addition, the capping layer 33 (see FIG. 6) may be removed during the planarization process.

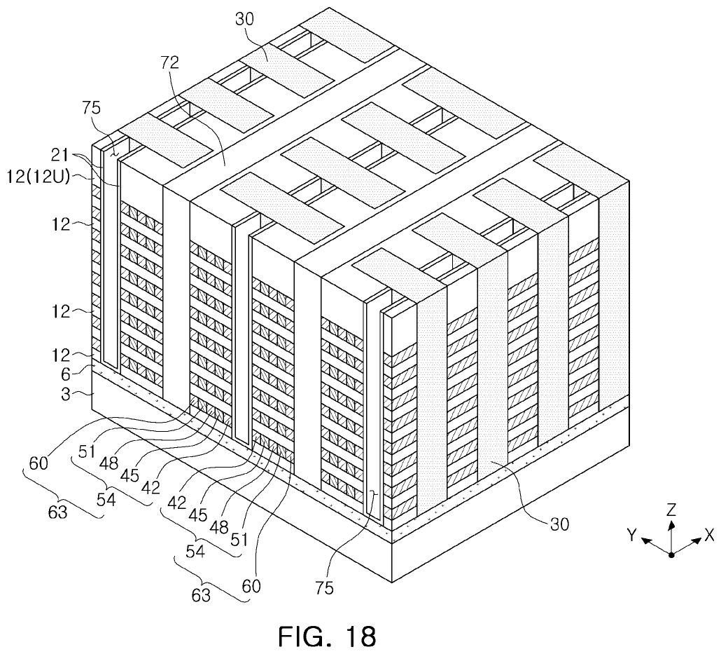

Referring to FIG. 18, holes 75 may be formed by removing the second layers 24 (see FIG. 17) of the vertical patterns 27. Thus, the first layers 21 of the vertical patterns 27 may be exposed.

Referring again to FIGS. 1A and 1B, in an example, after removing the first layers 21 (see FIG. 18), vertical structures 84 may be formed in the holes 75 (see FIG. 18). The vertical structures 84 may include external patterns 78 conformally covering sidewalls and internal walls of the holes 75 (see FIG. 18), and internal patterns 81 disposed on the external patterns 78 to fill the holes 75 (see FIG. 18). The external patterns 78 may include a metal nitride such as TiN or the like, and the internal patterns 81 may include a metal such as tungsten (W), having higher electrical conductivity than that of the external patterns 78.

In another example, the internal patterns 81 may be formed in the holes 75 (see FIG. 18) without removing the first layers 21 (see FIG. 18). In this case, the first layers 21 (see FIG. 18) may be defined as the external patterns 78. Thus, vertical structures 84 may be formed to include the external patterns 78 and the internal patterns 81. In this case, the external patterns 78, which may be formed as the first layers 21 (see FIG. 18) remain, may be formed of polysilicon or polysilicon-germanium having the same conductivity type as that of the first semiconductor region 42, and the internal patterns 81 may be formed of a material having higher electrical conductivity than that of the external patterns 78, for example, formed of a metal nitride such as TiN or the like and/or a metal such as W or the like.

Subsequently, contact plugs 90 and second conductive patterns 93 may be formed on the vertical structures 84 in sequence. The contact plugs 90 and the second conductive patterns 93 may be formed of a metal such as tungsten, aluminum, copper, or the like.

In example embodiments, the first conductive patterns 60, 160 and 260 may be bit lines, and the vertical structures 84, 184 and 284 may be word lines. Alternatively, the first conductive patterns 60, 160 and 260 may be word lines, and the vertical structures 84, 84′, 184, 184′, 284 and 284′ may be bit lines, depending on a circuit design.

In example embodiments, the horizontal structures 63, 163 and 263 may include a plurality of semiconductor regions 54, 154 and 254 that may constitute PNPN thyristor memory cells, respectively. The plurality of semiconductor regions 54, 154 and 254 that may include such PNPN thyristor memory cells, may be arranged three-dimensionally. Thus, the semiconductor device according to example embodiments may include memory cells that may be arranged three-dimensionally, thereby improving the degree of integration.

In example embodiments, the horizontal structures 63′, 163′ and 263′ may include the plurality of semiconductor regions 54′, 154′ and 254′ that may constitute PN diodes as switching devices, and data storage elements 57, 157 and 257. The data storage elements 57, 157 and 257 may be arranged three-dimensionally. Thus, the semiconductor device according to example embodiments may include switching devices and data storage elements, which may be arranged three-dimensionally, thereby improving the degree of integration.

As set forth above, according to example embodiments, horizontal structures may include semiconductor regions having different conductivity types while being sequentially arranged in a direction away from sides of vertical structures. The horizontal structures may include memory cells or data storage elements. Thus, since three-dimensionally arranged memory cells or data storage elements may be provided, the degree of integration of a semiconductor device may be improved.

While example embodiments have been shown and described above, it will be apparent to those skilled in the art that modifications and variations could be made without departing from the scope of the present inventive concept as defined by the appended claims.

What is claims is:

1. A method of forming a semiconductor device, comprising:
forming a stacked structure on a semiconductor substrate, wherein the stacked structure comprises interlayer insulating layers and sacrificial layers alternately and repeatedly stacked on the semiconductor substrate;
forming a vertical pattern including a semiconductor layer and penetrating through the stacked structure, wherein the vertical pattern includes a first side and a second side opposing the first side;
forming trenches exposing the sacrificial layers while penetrating through the stacked structure, wherein the trenches comprise a first trench and a second trench adjacent to the first trench;
forming first and second empty spaces by removing the sacrificial layers exposed, to expose the semiconductor layer of the vertical pattern, wherein the first empty spaces are formed between the first trench and the vertical pattern and the second empty spaces are formed between the second trench and the vertical pattern;
forming a plurality of semiconductor regions in the first and second empty spaces, the plurality of semiconductor regions being formed of a semiconductor material epitaxially grown from the semiconductor layer exposed; and
forming first and second separation structures filling the first and second trenches,
wherein the vertical pattern is located between the first trench and the second trench,
wherein the first trench faces the first side of the vertical pattern and the second trench faces the second side of the vertical pattern, and
wherein the stacked structure comprises a first stacked portion between the first trench and the first side of the vertical pattern and a second stacked portion between the second trench and the second side of the vertical pattern.

2. The method of claim 1, wherein the plurality of semiconductor regions comprise semiconductor regions having different conductivity types and forming a PN junction.

3. The method of claim 1, wherein the plurality of semiconductor regions partially fill the first and second empty spaces, and
wherein the method further comprises forming first and second conductive patterns filling a remainder of the first and second empty spaces, after forming the plurality of semiconductor regions and before forming the first and second separation structures.

4. The method of claim 3, further comprising forming data storage elements in contact with the plurality of semiconductor regions, in the first and second empty spaces, before forming the first and second conductive patterns.

5. The method of claim 4, wherein each of the data storage elements comprises a resistance variable element.

6. The method of claim 3, further comprising:
forming a hole by partially removing the vertical pattern or removing the entirety of the vertical pattern after forming the first and second separation structures; and
forming a vertical structure in the hole,
wherein the vertical structure comprises a conductive material.

7. The method of claim 6, further comprising conductive line electrically connected the vertical structure,
wherein each of the first and second conductive patterns extends in a first direction parallel to an upper surface of the semiconductor substrate, and
wherein the conductive line extends in a second direction parallel to the upper surface of the semiconductor substrate and perpendicular to the first direction.

8. The method of claim 1, wherein the plurality of semiconductor regions comprise a first semiconductor region, a second semiconductor region, a third semiconductor region, and a fourth semiconductor region,
wherein the first semiconductor region, the second semiconductor region, the third semiconductor region, and the fourth semiconductor region are sequentially arranged in a direction away from a side surface of the vertical pattern and parallel to an upper surface of the semiconductor substrate,
wherein the first and third semiconductor regions have a first conductivity type,
wherein the second and fourth semiconductor regions have a second conductivity type different from the first conductivity type, and
wherein the first to fourth semiconductor regions constitute a PNPN thyristor memory cell.

9. The method of claim 1, wherein the first and second separation structures are formed of an insulating material.

10. A method of forming a semiconductor device, comprising:
forming a stacked structure on a semiconductor substrate, wherein the stacked structure comprises interlayer insulating layers and sacrificial layers alternately and repeatedly stacked on the semiconductor substrate;
forming a vertical pattern including a semiconductor layer and penetrating through the stacked structure, wherein the vertical pattern includes a first side and a second side opposing the first side;
forming trenches penetrating the stacked structure, wherein the trenches comprise a first trench and a second trench adjacent to the first trench, wherein the first and second trenches expose the sacrificial layers of the stacked structure;
forming first and second empty spaces by removing the sacrificial layers exposed, to expose the semiconductor layer of the vertical pattern, wherein the first empty spaces are formed between the first trench and the vertical pattern and the second empty spaces are formed between the second trench and the vertical pattern;
forming a plurality of semiconductor regions in the first and second empty spaces; and
forming first and second separation structures filling the first and second trenches,
wherein the vertical pattern is located between the first trench and the second trench,
wherein the first trench faces the first side of the vertical pattern and the second trench faces the second side of the vertical pattern, and
wherein the stacked structure comprises a first stacked structure between the first trench and the first side of the vertical pattern and between the second trench and the second side of the vertical pattern.

11. The method of claim 10, wherein the vertical pattern comprises a semiconductor layer, and
wherein the plurality of semiconductor regions are formed of a semiconductor material epitaxially grown from the semiconductor layer of the vertical pattern.

12. The method of claim 10, wherein the plurality of semiconductor regions comprises a first semiconductor region, a second semiconductor region, a third semiconductor region, and a fourth semiconductor region,
wherein the first semiconductor region, the second semiconductor region, the third semiconductor region, and the fourth semiconductor region are sequentially arranged in a direction away from a side surface of the vertical pattern and parallel to an upper surface of the semiconductor substrate,
wherein the first and third semiconductor regions have a first conductivity type,
wherein the second and fourth semiconductor regions have a second conductivity type different from the first conductivity type, and
wherein the first to fourth semiconductor regions constitute a PNPN thyristor memory cell.

13. The method of claim 10, wherein the plurality of semiconductor regions partially fill the first and second empty spaces, and
wherein the method further comprises forming first and second conductive patterns filling a remainder of the first and second empty spaces, before forming the first and second separation structures.

14. The method of claim 13, further comprising:
forming first data storage elements in contact with the plurality of semiconductor regions in the first empty spaces; and
forming second data storage elements in contact with the plurality of semiconductor regions in the second empty spaces, before forming the first and second conductive patterns.

15. The method of claim 13, further comprising:
forming a hole by partially removing the vertical pattern or removing the entirety of the vertical pattern after forming the first and second separation structures; and
forming a vertical structure in the hole,
wherein the vertical structure comprises a conductive material.

16. A method of forming a semiconductor device, comprising:
forming a stacked structure on a semiconductor substrate, wherein the stacked structure comprises interlayer insulating layers and sacrificial layers alternately and repeatedly stacked on the semiconductor substrate;
forming a vertical pattern penetrating through the stacked structure, the vertical pattern including a semiconductor layer, wherein the vertical pattern includes a first side and a second side opposing the first side;
forming first and second partition walls penetrating through the stacked structure, wherein the first and second partition walls are formed before or after forming the vertical pattern;
forming trenches exposing the sacrificial layers while penetrating through the stacked structure, wherein the trenches comprise a first trench and a second trench adjacent to the first trench;
forming first and second empty spaces by removing the sacrificial layers exposed, to expose the vertical pattern, wherein the first empty spaces are formed between the first trench and the vertical pattern and the second empty spaces are formed between the second trench and the vertical pattern;
forming a plurality of first semiconductor regions in the first empty spaces and a plurality of second semiconductor regions in the second empty spaces; and
forming first and second separation structures filling the first and second trenches,
wherein the vertical pattern is formed between the first partition wall and the second partition wall,
wherein the vertical pattern and the first and second partition walls are formed between the first trench and the second trench, and
wherein the stacked structure comprises a first stacked portion between the first trench and the first side of the vertical pattern and a second stacked portion between the second trench and the second side of the vertical pattern.

17. The method of claim 16, wherein the vertical pattern comprises a semiconductor layer, and
wherein the plurality of first and second semiconductor regions are formed of a semiconductor material epitaxially grown from the semiconductor layer of the vertical pattern.

18. The method of claim 16, wherein the first and second partition walls are formed of an insulating material, and
wherein the vertical pattern is formed between the first partition wall and the second partition wall.

19. The method of claim 16, wherein a width in a first direction of each of the first and second partition walls is greater than a width in the first direction of the vertical pattern,
wherein the first direction is parallel to an upper surface of the semiconductor substrate, and
wherein each of the first and second separation structures extends in a second direction parallel to the upper surface of the semiconductor substrate and perpendicular to the first direction.

20. The method of claim 16, wherein the plurality of first and second semiconductor regions partially fill the first and second empty spaces,
wherein the method further comprises forming first and second conductive patterns filling a remainder of the first and second empty spaces, before forming the first and second separation structures,
wherein the first separation structure is spaced apart from the first partition wall by the first conductive patterns, and
wherein the second separation structure is spaced apart from the second partition wall by the second conductive patterns.
